(19) United States
(12) Patent Application Publication
(10) Pub. No.: US 2007/0289531 A1
(43) Pub. Date: Dec. 20, 2007

(54) BATCH-TYPE DEPOSITION APPARATUS HAVING A GLAND PORTION

(75) Inventors: Kyoung-Hwan HWANG, Gyeonggi-do (KR); Jin-Sung KIM, Gyeonggi-do (KR); Chang-Hyuk OK, Gyeonggi-do (KR); Jai-Young WOO, Gyeonggi-do (KR); Min-Ho CHOI, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/849,927

(22) Filed: Sep. 4, 2007

Related U.S. Application Data
(62) Division of application No. 11/025,005, filed on Dec. 28, 2004.

(30) Foreign Application Priority Data
Jan. 29, 2004 (KR) 2004-5866

(51) Int. Cl. C23C 16/00

(52) U.S. Cl. 118/716

(57) ABSTRACT

Batch-type deposition apparatus having a gland portion are provided. The apparatus include a reaction furnace, a gas nozzle located in the reaction furnace, a gas supply conduit located outside the reaction furnace and a gland portion for connecting the gas nozzle to the gas supply conduit. The gland portion includes a gas nozzle end extended from the gas nozzle toward an outside region of the reaction furnace and a gas supply conduit end extended from the gas supply conduit. The gas nozzle end is connected to the gas supply conduit end through a buffer member. The buffer member has an inclined inner wall for connecting an inner wall of the gas nozzle end to that of the gas supply conduit end.

### CROSS REFERENCE TO RELATED APPLICATION

This application is a Continuation of U.S. patent application Ser. No. 11/025,005, filed on Dec. 28, 2004, now pending, which claims the benefit of Korean Patent Application No. 2004-5866, filed Jan. 29, 2004, the contents of which are hereby incorporated herein by reference in their entirety.

### BACKGROUND OF THE INVENTION

1. Field of the Invention

The present invention relates to apparatus used in fabrication of semiconductor devices and, more particularly, to batch-type deposition apparatuses having a gland portion.

2. Description of Related Art

In fabrication of semiconductor devices, a thin film deposition process is widely used in formation of conductive layers, semiconductor layers or insulating layers. The thin film deposition process is mainly performed using a sputtering technique or a chemical vapor deposition technique.

The chemical vapor deposition (CVD) technique provides a dense film and excellent step coverage as compared to the sputtering technique. Thus, the CVD technique is widely used in fabrication of highly integrated semiconductor devices.

The CVD apparatus is described in U.S. Patent Publication No. US2003/0164143 A1 to Toyoda, et al., entitled “Batch-type remote plasma processing apparatus.” According to Toyoda, et al., the CVD apparatus includes a vertical furnace that provides a space for the thin film deposition process. In addition, the CVD apparatus includes a gas introducing portion for injecting process gases into the vertical furnace, namely, a gland portion of a gas nozzle.

Recently, an atomic layer deposition (ALD) process has become widely used as a technique for depositing the thin films. The ALD process is carried out at a relatively low temperature as compared to the conventional CVD process. Nevertheless, the ALD process exhibits better step coverage as compared to the CVD process. Thus, the ALD process is very attractive as the thin film deposition process for fabricating the highly integrated semiconductor devices. The ALD apparatus may be classified into either a single wafer type apparatus or a batch type apparatus. The batch type apparatus has an advantage of high throughput as compared to the single wafer type apparatus.

FIG. 1 is a cross-sectional view illustrating a gland portion of a gas nozzle employed in the conventional batch type ALD apparatus. Reference characters A and B indicate inside and outside regions of a vertical furnace, respectively.

Referring to FIG. 1, the gland portion 13 includes a gas nozzle end 1e extending from gas nozzle 1 provided within the inside region A of the vertical furnace. The gas nozzle end 1e penetrates a sidewall of a flange 5 attached to the vertical furnace and extends toward the outside region B of the vertical furnace. The gas nozzle 1 and the gas nozzle end 1e are formed of material that can withstand high temperature. In general, the gas nozzle 1 and the gas nozzle end 1e are comprised of quartz. The gas nozzle end 1e is connected to a gas supply conduit 3. The gas supply conduit 3 includes a gas supply conduit end 3e, and a joint portion 3j extending from the gas supply conduit end 3e. The joint portion 3j surrounds a portion of the gas nozzle end 1e. The gas supply conduit end 3e and the joint portion 3j are formed of a metallic material such as stainless steel (SUS).

The gas supply conduit end 3e has a first inner diameter D1, and the joint portion 3j has a second inner diameter D2 which is greater than the first inner diameter D1. As a result, there exists an abrupt diameter difference between the gas supply conduit end 3e and the joint portion 3j In addition, the gas nozzle end 1e is spaced apart from the gas supply conduit end 3e by a distance denoted S. This configuration is provided for preventing the gas nozzle end 1e and the gas supply conduit end 3e from physically contacting each other when the gas nozzle end 1e thermally expands.

If a process gas G is introduced into the vertical furnace through the above-mentioned conventional gland portion 13, a vortex of the process gas G may be created within the joint portion 3j as shown in FIG. 1. The vortex of the process gas G is generated due to the above-mentioned abrupt diameter difference. In this case, a portion of the process gas G may be easily deposited onto the inner wall of the joint portion 3j to thereby form a solid-state contaminant. Such contaminant may act as a particle source. In particular, when the process gas G is a precursor having a high molecular weight, the contaminant may be more easily generated.

### SUMMARY OF THE INVENTION

Embodiments of the invention provide batch-type deposition apparatus having a gland portion that is suitable for suppressing the generation of contaminant particles.

Other embodiments of the invention provide batch-type atomic layer deposition apparatus having a gland portion suitable for suppressing the formation of contaminant particles.

In one aspect, the apparatus comprises a reaction furnace, a gas nozzle located in the reaction furnace, a gas supply conduit installed outside the reaction furnace, and a gland portion for connecting the gas nozzle to the gas supply conduit. The gland portion includes a gas nozzle end extending from the gas nozzle toward an outside region of the reaction furnace, a gas supply conduit end extending from the gas supply conduit, and a buffer member for connecting the gas nozzle end to the gas supply conduit end. The buffer member has an inclined inner wall for connecting an inner wall of the gas nozzle end to an inner wall of the gas supply conduit end.

In one embodiment of the present invention, an angle between an extension line of the inclined inner wall and a central axis of the buffer member may be less than about 90°.

In another embodiment, an inner diameter of the gas nozzle end may be greater than that of the gas supply conduit end.

In still another embodiment, the batch-type deposition apparatus may additionally includes a joint portion extending from the gas supply conduit end to surround the buffer member and the gas nozzle end, and a connector member between the gas supply conduit end and the joint portion. When the inner diameter of the gas nozzle end is greater than that of the gas supply conduit end, the gas supply conduit end and the joint portion may be in contact with inner and outer edges of the connector member, respectively.

In yet further embodiment, the buffer member may extend from the gas nozzle end to contact with the gas supply conduit end. In this case, the buffer member and the gas nozzle end may be a unitary body.

In additional embodiments, the buffer member may extend from the gas supply conduit end to contact the gas nozzle end. In this case, the buffer member and the gas supply conduit end may be a unitary body.

In still further embodiment, the buffer member may extend from the gas supply conduit end so as to cover the inner wall of the gas nozzle end. In this case, the inclined inner wall may overlap with the gas nozzle end.

In yet additional embodiment, the buffer member may be an independent member that is spaced apart from the gas nozzle end and the gas supply conduit end.

The foregoing and other objects, features and advantages of the invention will be apparent from the more particular description of preferred embodiments of the invention, as illustrated in the accompanying drawings. The drawings are not necessarily to scale, emphasis instead being placed upon illustrating the principles of the invention.

### BRIEF DESCRIPTION OF THE DRAWINGS

FIG. 1 is a cross-sectional view illustrating a gland portion of a gas nozzle employed in a conventional atomic layer deposition apparatus.

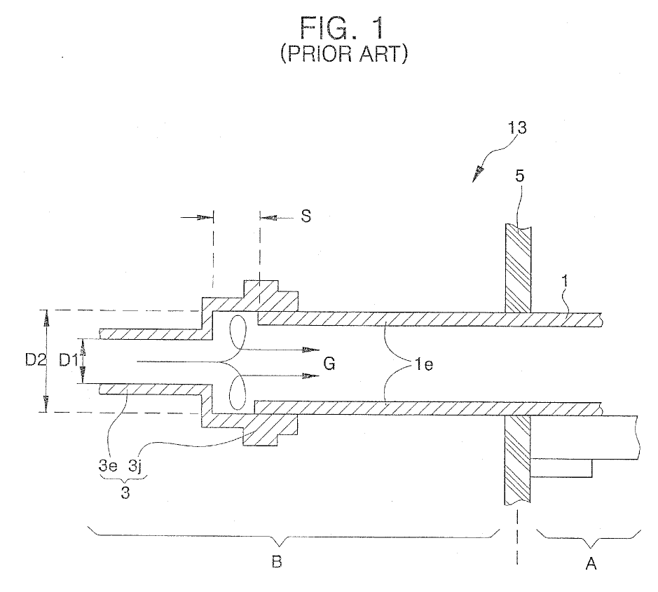

FIG. 2 is a schematic cross-sectional view illustrating a batch type atomic layer deposition apparatus in accordance with embodiments of the present invention.

FIG. 3 is a cross-sectional view illustrating a gland portion of a batch type atomic layer deposition apparatus in accordance with one embodiment of the present invention.

FIG. 4 is a cross-sectional view illustrating a gland portion of a batch type atomic layer deposition apparatus in accordance with another embodiment of the present invention.

FIG. 5 is a cross-sectional view illustrating a gland portion of a batch type atomic layer deposition apparatus in accordance with still another embodiment of the present invention.

FIG. 6 is a cross-sectional view illustrating a gland portion of a batch type atomic layer deposition apparatus in accordance with still yet another embodiment of the present invention.

### DETAILED DESCRIPTION OF THE INVENTION

The present invention will now be described more fully hereinafter with reference to the accompanying drawings, in which exemplary embodiments of the invention are shown. Like reference numbers denote like elements throughout the specification.

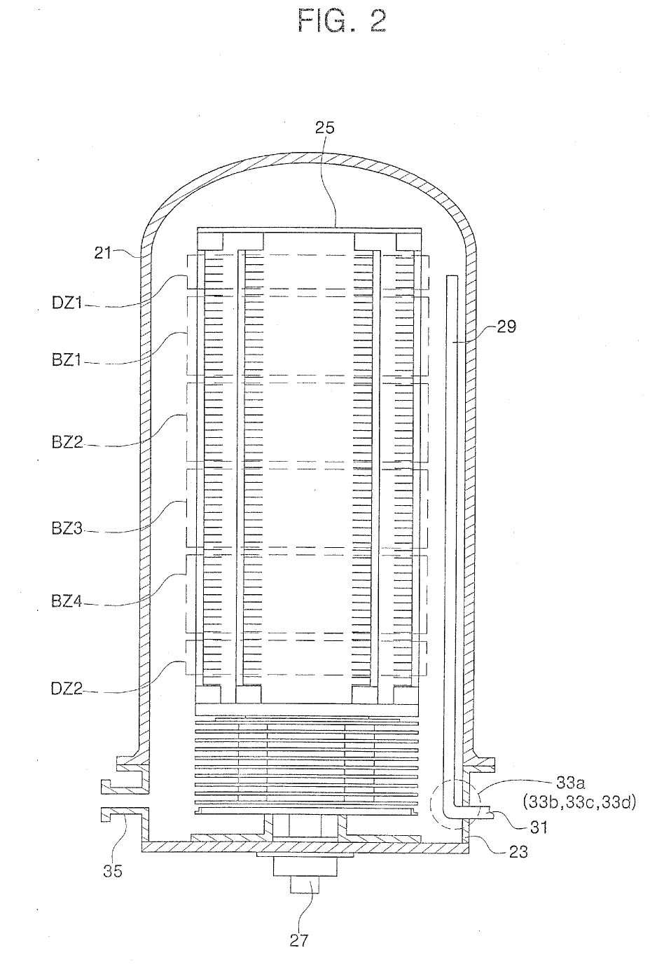

FIG. 2 is a schematic cross-sectional view illustrating a batch type atomic layer deposition apparatus in accordance with embodiments of the present invention.

Referring to FIG. 2, the batch-type atomic layer deposition apparatus comprises a reaction furnace 21, e.g., a vertical furnace. The vertical furnace 21 provides a space where a thin film deposition process, namely, an atomic layer deposition process is carried out. The vertical furnace 21 may be formed of material that can endure high temperature of about 1200 degrees. For example, the vertical furnace may be a quartz furnace. A flange 23 may be attached to a lower portion of the vertical furnace 21. The flange 23 may be made of metal such as stainless steel. A boat 25 may be loaded into the vertical furnace 21 through the flange 23. The boat 25 has a plurality of slots into which semiconductor wafers are inserted. The boat 25 may be divided into a plurality of batch zones. For example, the boat 25 may be divided into four batch zones BZ1, BZ2, BZ3 and BZ4 as shown in FIG. 2. Thus, each of the batch zones can have slots in which twenty-five to fifty semiconductor wafers can be inserted. In addition, the boat 25 may further include first and second dummy zones, DZ1 and DZ2, which are positioned over and under the batch zones BZ1, BZ2, BZ3 and BZ4, respectively. The dummy zones DZ1 and DZ2 have slots where dummy wafers are inserted. The dummy wafers are loaded in order to enhance process uniformity.

A motor 27 may be provided below the boat 25. The motor 27 rotates the boat 25 while the thin film deposition process, e.g., an atomic layer deposition process, is performed inside the vertical furnace 21. As a result, uniform thin films may be formed on the semiconductor wafers in the boat 25.

A gas nozzle 29 is provided in the vertical furnace 21. Process gases are supplied toward the semiconductor wafers in the boat 25 loaded into the vertical furnace 21 through the gas nozzle 29. The gas nozzle 29 may also be a quartz conduit that can endure at a high temperature. The gas nozzle 29 is connected to a gas supply conduit 31 disposed outside the vertical furnace 21 through a gland portion 33a, 33b, 33c or 33d. The gland portion 33a, 33b, 33c or 33d is installed to penetrate a portion of the flange 23.

Air in the vertical furnace 21 and/or byproduct generated in the vertical furnace 21 are vented through an exhaust line 35 branched from the flange 23.

The process gases introduced into the vertical chamber 21 through the gas nozzle 29 may include at least one among various precursors. For example, when the atomic layer deposition process is performed to form a hafnium oxide layer, the process gases may include hafnium butoxide (Hf(OC₄H₉)₄) or tetrakis ethyl methyl amino hafnium (Hf(NCH₃C₂H₅)₄; TEMAH). In addition, the process gases may further include an oxidation gas such as an oxygen gas or an ozone gas.

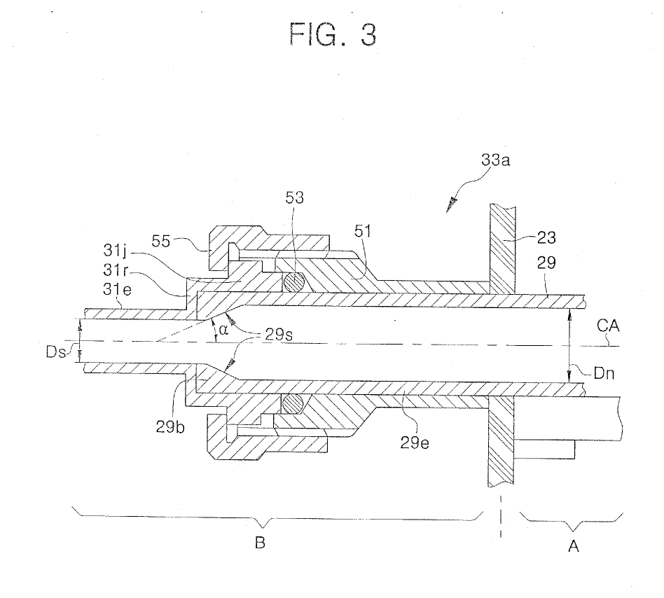

FIG. 3 is a cross-sectional view illustrating a first gland portion 33a employed in a batch-type atomic layer deposition apparatus in accordance with one embodiment of the present invention. In the drawing, reference characters A and B indicate inside and outside regions of the vertical furnace 21 shown in FIG. 2, respectively.

Referring to FIG. 2 and FIG. 3, the first gland portion 33a includes a gas nozzle end 29e extended from the gas nozzle 29 to penetrate a portion of the flange 23 and a buffer member 29b extended from the gas nozzle end 29e. The gas nozzle end 29e is located in the outside region B of the vertical furnace 21 and has an inner diameter Dn. The gas nozzle 29, the gas nozzle end 29e and the buffer member 29b constitute a unitary nozzle portion. The unitary nozzle portion is preferably formed of quartz that can endure at a high temperature of about 1200 degrees.

The buffer member 29b is in contact with the gas supply conduit end 31e extended from the gas supply conduit 31. Thus, the process gases introduced into the gas supply conduit 31 are injected into the vertical furnace 21 through the gas supply conduit end 31e, the buffer member 29b, the gas nozzle end 29e and the gas nozzle 29. The gas supply conduit end 31e has an inner diameter Ds. The buffer member 29b and the gas nozzle end 29e may be surrounded by a joint portion 31j and a ring-type connector 31r, which are extended from the gas supply conduit end 31e. In this case, the gas supply conduit end 31e, the ring-type connector 31r and the joint portion 31j may be a unitary SUS conduit.

When the inner diameter Dn of the gas nozzle end 29e is greater than the inner diameter Ds of the gas supply conduit end 31e, the gas supply conduit end 31e and the joint portion 31j are in contact with inner and outer edges of the ring-type connector 31r, respectively. In particular, the buffer member 29b has an inclined inner wall 29s that connects an inner wall of the gas supply conduit end 31e to an inner wall of the gas nozzle end 29e. An angle α between a central axis CA of the gas nozzle end 29e and an extension line of the inclined inner wall 29s is less than about 90°. As a result, while the process gases introduced into the gas supply conduit end 31e pass through the buffer member 29b, the formation of a vortex of the process gases can be avoided. In other words, the inclined inner wall 29s allows the process gases passing through the buffer member 29b to smoothly flow without creating any vortex.

The joint portion 31j, and the gas nozzle end 29e adjacent to the joint portion 31j, may be surrounded by a union 51. In addition, the gas nozzle end 29e between the union 51 and the joint portion 31j may be surrounded by an O-ring 53. Furthermore, the joint portion 31j and the union 51 may be surrounded by a nut 55. The union 51, the O-ring 53, and the nut 55 are members for preventing process gases from passing through the gas supply conduit end 31e, and for preventing the buffer member 29b from leaking.

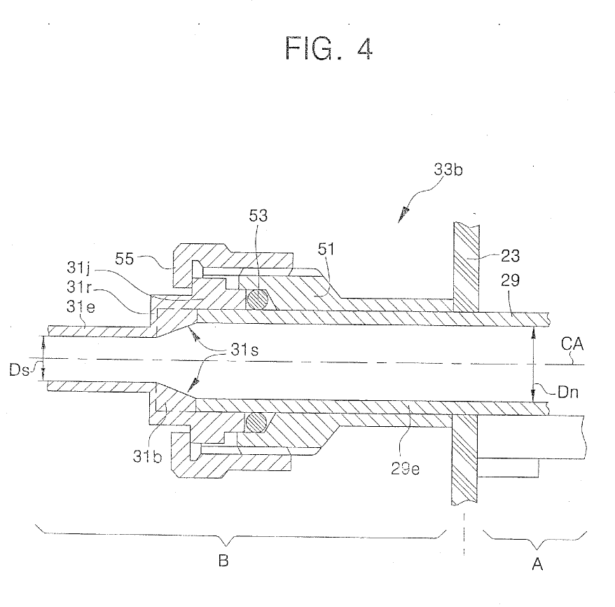

FIG. 4 is a cross-sectional view illustrating a second gland portion 33b employed in an atomic layer deposition apparatus in accordance with another embodiment of the present invention. In the drawing, reference characters A and B indicate inside and outside regions of the vertical furnace 21 shown in FIG. 2, respectively. The second gland portion 33b is different from the first gland portion 33a of FIG. 3 in terms of a buffer member. Thus, a description will be directed only to the buffer member for simplicity of description.

Referring to FIG. 2 and FIG. 4, the second gland portion 33b has a buffer member 31b that extends from the gas supply conduit end 31e and is in contact with the gas nozzle end 29e, instead of the buffer member 29b of the first gland portion 33a. The gas supply conduit end 31e, the ring-type connector 31r, the joint portion 31j, and the buffer member 31b can be a unitary SUS conduit structure. The buffer member 31b also has an inclined inner wall 31s similar to the buffer member 29b of the first gland portion 33a. Thus, process gases passing through the second gland portion 33b may also smoothly flow without forming any vortex.

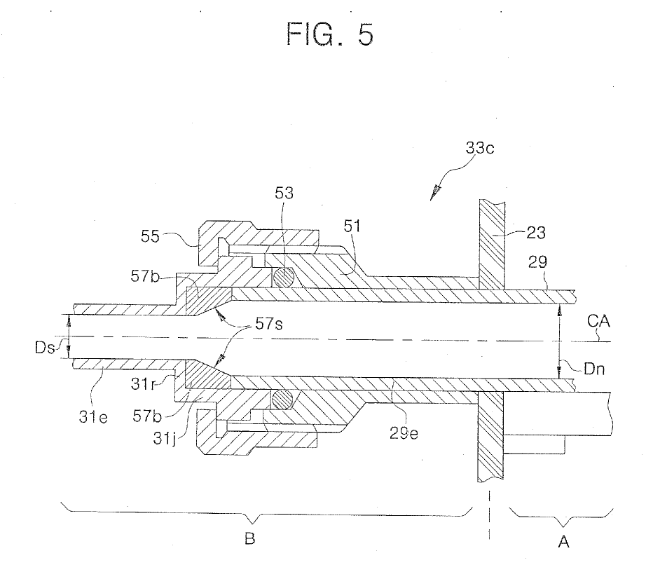

FIG. 5 is a cross-sectional view illustrating a third gland portion 33c employed in an atomic layer deposition apparatus in accordance with still another embodiment of the present invention. In the drawing, reference characters A and B indicate inside and outside regions of the vertical furnace 21 shown in FIG. 2, respectively. The third gland portion 33c is different from the first and second gland portions 33a and 33b of FIG. 3 and FIG. 4 in terms of its buffer member. Thus, a description will be will be directed only to the buffer member.

Referring to FIG. 2 and FIG. 5, the third gland portion 33c has a buffer member 57b separated from the gas nozzle end 29e and the gas supply conduit end 31e, instead of the buffer member 29b or 31b shown in FIG. 3 or FIG. 4, respectively. The buffer member 57b is interposed between the gas nozzle end 29e and the gas supply conduit end 31e and may be formed of resilient material such as SUS. The buffer member 57b also has an inclined inner wall 57s that connects an inner wall of the gas supply conduit end 31e to an inner wall of the gas nozzle end 29e. Thus, process gases passing through the third gland portion 33c may also smoothly flow without creating any vortex because of the presence of the inclined inner wall 57s.

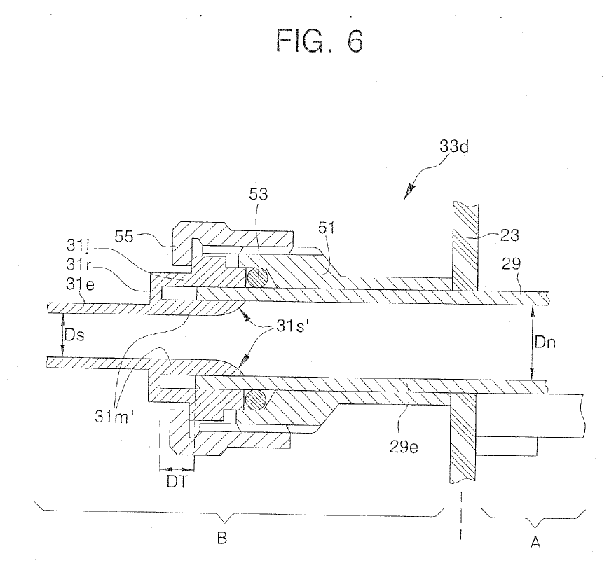

FIG. 6 is a cross-sectional view illustrating a fourth gland portion 33d employed in an atomic layer deposition apparatus in accordance with still yet another embodiment of the present invention. In the drawing, reference characters A and B indicate inside and outside regions of the vertical furnace 21 shown in FIG. 2, respectively. The fourth gland portion 33d is different from the first through third gland portions 33a, 33b and 33c in terms of its buffer member. Thus, a description will be directed only to the buffer member.

Referring to FIG. 2 and FIG. 6, the fourth gland portion 33d has a buffer member 31m′ extending from the gas supply conduit end 31e to cover the inner wall of the gas nozzle end 29e, instead of the buffer member 29b, 31b, or 57b as shown in FIG. 3, FIG. 4, or FIG. 5, respectively. When the gas nozzle end 29e is thermally expanded, the gas nozzle end 29e may interact or collide with the gas supply conduit end 31e, and more specifically, the ring-type connector 31r, to form particles. Thus, the gas nozzle end 29e is preferably spaced apart from the ring-type connector 31r by an interval DT as shown in FIG. 6 to avoid such interactions. The buffer member 31m′ is extended so as to cover a space between the gas nozzle end 29e and the ring-type connector 31r.

The buffer member 31m′ also has an inner wall which connects an inner wall of the gas supply conduit end 31e to an inner wall of the gas nozzle end 29e. In this case, the inner wall of the buffer member 31m′ may include an inclined inner wall 31s′ that overlaps the gas nozzle end 29e. The inclined inner wall 31s′ can have a rounded profile. As a result, process gases passing through the fourth gland portion 33d can also smoothly flow without creating any vortex because of the presence of the inclined inner wall 31s′.

As mentioned above, a process gas passing through the buffer member of the gland portion employed in the batch-type deposition apparatus may smoothly flow without any vortex due to the presence of the inclined inner wall of the buffer member. As a result, it can significantly reduce a probability that a portion of the process gas is adhered to the gland portion and hardened itself to thereby generate contaminants such as particles. In particular, even though the process gas is a precursor having a high molecular weight, for example, Hf(OC₄H₉)₄ or Hf(NCH₃C₂H₅)₄, used in the atomic layer deposition process, the process gas may smoothly flow creating without any vortex because of the presence of the inclined inner wall of the buffer member. As a result, it can prevent the formation of particles within the gland portion.

Preferred embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A batch-type deposition apparatus, comprising:
a reaction furnace;
a gas nozzle installed inside the reaction furnace;
a gas supply conduit located outside the reaction furnace; and
a gland portion for connecting the gas nozzle to the gas supply conduit, the gland portion comprising:
a gas nozzle end extending from the gas nozzle toward an outside region of the reaction furnace and having an inner diameter which is greater than an inner diameter of the gas supply conduit end;
a gas supply conduit end extending from the gas supply conduit; and
a buffer member connecting the gas nozzle end to the gas supply conduit end and having an inclined inner wall that connects an inner wall of the gas nozzle end to an inner wall of the gas supply conduit end,
the buffer member extending from the gas supply conduit end and covering an inner wall of the gas nozzle end, and the inclined inner wall of the buffer member overlapping the gas nozzle end.

2. The batch-type deposition apparatus as recited in claim 1, wherein an angle formed between an extension line of the inclined inner wall and a central axis of the buffer member is less than about 90°.

3. The batch-type deposition apparatus as recited in claim 1, further comprising:
a joint portion extending from the gas supply conduit end and surrounding the buffer member and the gas nozzle end; and
a connector member located between the gas supply conduit end and the joint portion, wherein the gas supply conduit end and the joint portion are in contact with the respective inner edge and outer edge of the connector member.

4. A batch-type atomic layer deposition apparatus, comprising:
a vertical furnace;
a gas nozzle located in the vertical furnace for introducing process gases into the vertical furnace;
a flange attached to a lower portion of the vertical furnace;
a gas nozzle end extending from the gas nozzle through a portion of the flange, the gas nozzle end extending toward an outside region of the vertical furnace;
a gas supply conduit located outside the vertical furnace for introducing the process gases into the gas nozzle;
a gas supply conduit end extending from the gas supply conduit; and
a buffer member extending from the gas supply conduit end, covering an inner wall of the gas nozzle end, and including an inclined inner wall for connecting an inner wall of the gas nozzle end to an inner wall of the gas supply conduit end.

5. The batch-type atomic layer deposition apparatus as recited in claim 4, wherein the gas nozzle and the gas nozzle end are a unitary quartz conduit.

6. The batch-type atomic layer deposition apparatus as recited in claim 4, further comprising:
a joint portion extending from the gas supply conduit end to surround the gas nozzle end; and
a ring-type connector located between the gas supply conduit end and the joint portion, wherein the gas supply conduit end and the joint portion are in respective contact with inner and outer edges of the ring-type connector.

7. The batch-type atomic layer deposition apparatus as recited in claim 6, wherein the gas nozzle end is spaced apart from the ring-type connector.

8. The batch-type atomic layer deposition apparatus as recited in claim 6, wherein the gas supply conduit end, the ring-type connector, the joint portion and the buffer member are a unitary body.

9. The batch-type atomic layer deposition apparatus as recited in claim 6, wherein the gas supply conduit end, the ring-type connector, the joint portion and the buffer member are composed of stainless steel.

10. The batch-type atomic layer deposition apparatus as recited in claim 4, wherein the gas supply conduit end has an inner diameter less than an inner diameter of the gas nozzle end.
